(19) United States
(12) Patent Application Publication
(10) Pub. No.: US 2015/0255652 A1
(43) Pub. Date: Sep. 10, 2015

(54) PHOTO-VOLTAIC DEVICE HAVING IMPROVED SHADING DEGRADATION RESISTANCE

(71) Applicant: Dow Global Technologies LLC, Midland, MI (US)

(72) Inventors: Abhijit Namjoshi, Freeport, TX (US); John McKeen, Midland, MI (US); Rebekah Feist, Midland, MI (US)

(21) Appl. No.: 14/430,298

(22) PCT Filed: Aug. 20, 2013
(86) PCT No.: PCT/US2013/055806

§ 371 Date: Mar. 23, 2015

Related U.S. Application Data
(60) Provisional application No. 61/707,535, filed on Sep. 28, 2012.

(51) Int. Cl. H01L 31/0475; G06F 17/50

(52) U.S. Cl. CPC H01L 31/0475; G06F 17/5072

(57) ABSTRACT

An article of manufacture includes an active solar area having a number of photovoltaic (PV) cell sets. Each of the PV cell sets includes one or more PV cells, and has a PV cell set area. Each of the PV cell sets includes a spacing distribution, where the spacing distribution is such that a geometric shape having a predetermined characteristic area value cannot be positioned to cover an area greater than a reverse biasing fraction of the PV cell set area corresponding to the PV cell set.

### FIELD

The present invention relates to improved photo-voltaic devices, and more particularly but not exclusively relates to photo-voltaic devices having an improved resistance to shading induced degradation.

### INTRODUCTION

Installed solar modules, for example within a building integrated photovoltaic (BIPV) device, are subject to partial shading from time to time. When a solar module is subjected to partial shading, a situation potentially occurs where a portion of the PV area of a series circuit is shaded and other portions of the same series circuit are still subject to incident light. Shaded portions of the PV area that are in series with illuminated portions of the PV area are subject to the possibility that the shaded portions will be subject to a reverse voltage bias. Presently known solar modules can manage the reverse bias situation by utilizing bypass diodes. However, the number of bypass diodes required to completely avoid the possibility of a reverse bias occurrence can be quite high, especially in thin-film applications where the reverse breakdown voltage of the cells can be relatively low compared to other applications. A high number of bypass diodes increases the cost and complexity of the device, and can reduce the usable area of the device for solar energy collection as accommodation is made for the inclusion of the diodes.

A reduction of the number of bypass diodes from the number required to avoid the possibility of reverse bias introduces the risk that individual PV areas will experience reverse bias. PV areas that are exposed to reverse bias suffer short term power reductions even after light is re-introduced, and can experience longer term or permanent degradation.

Among the literature that can pertain to this technology includes the article Y. J. Wang and P. C. Hsu, “An investigation on partial shading of PV modules with different connection configurations of PV cells,” International Journal on Energy, vol. 36, no. 5, pp. 3069-3078, 2011.

### SUMMARY

The present disclosure in one aspect includes an article of manufacture having an active solar area defining a number of photovoltaic (PV) cell sets, each PV cell set having a PV cell set area. The article further includes each of the PV cell sets having a spacing distribution such that a geometric shape having a predetermined characteristic area value cannot be positioned to cover greater than a reverse biasing fraction of the PV cell set area of the corresponding PV cell set.

In certain additional or alternative aspects, the disclosure includes an article having one or more of the following features: the article where each of the PV cell sets further includes a number of PV cells electrically coupled in a parallel arrangement and wherein the PV cell set area corresponding to each of the PV cell sets consists of the total area of the number of PV cells of the PV cell set; the article further includes a number of notional geometric regions, where each of the notional geometric regions includes a height of at least two PV cell heights, a width of at least two PV cell widths, and wherein each of the PV cell sets includes PV cells from the number of cells distributed to a plurality of the notional geometric regions; the article having between three and six notional regions, inclusive: the article having notional geometric regions each having an equal area; the article where each of the PV cell sets includes at least one PV cell positioned within each of the notional geometric regions; the article where each PV cell set includes PV cells having an even distribution throughout the notional geometric regions. An example and non-limiting equal distribution includes: an equal number of PV cells from each PV cell set to each notional geometric region; an equal area of PV cells from each PV cell set to each notional geometric region; a prorated number of PV cells from each PV cell set to each notional geometric region; the prorated number determined in response to an area of each notional geometric region; a prorated area of PV cells from each PV cell set to each notional geometric region, the prorated area determined in response to an area of each notional geometric region; and/or any one of the preceding distributions further including a rounding adjustment.

In certain additional or alternative aspects, the disclosure includes an article having one or more of the following features: the article where the predetermined characteristic area value includes an areal fraction of the active solar area selected from the areal fractions consisting of: between ⅓^{rd} and ½^{th}, between ½ and 1/10^{th}, between ½ and 1/15^{th}, and between ½ and 1/20^{th}, each range being inclusive; the article where the geometric shape includes a circle, an ellipse, a regular polygon, a square, a rectangle, a triangle, a quadrilateral, and/or a trapezoid; the article where the reverse biasing fraction includes a value between a minimal fractional area and a maximal fraction area inclusively, where the minimal fractional area is an area that causes reverse biasing in the corresponding PV cell set and where the maximal fractional area is an area that activates a bypass diode electrically coupled to the corresponding PV cell set; the article having the PV cell sets arranged in a concentric framing arrangement; and the concentric framing arrangement wherein an inner PV cell set includes an excursive portion extending toward an outer edge of the solar active area.

An example article includes the PV cell sets including a PV cell material, where the number of series PV cell sets associated with a bypass diode includes a value greater than n from the equation:

$$n = \frac{{V}_{bypass} - {V}_{b}}{( 1 + β ( T - {T}_{0} ) ) {V}_{c}}$$

In the equation, n includes a nominal maximum number of series PV cell sets per bypass diode, V_{bypass} includes a bypass diode activation voltage, V_{b} includes a reverse breakdown voltage of the PV cell set material, V_{c} includes an operating voltage of the PV cell material when illuminated, T includes an operating temperature, T₀ includes a reference temperature, and β includes a voltage temperature coefficient.

The present disclosure in an additional or alternative aspect includes a method having operations including: interpreting a modular current-voltage (IV) characteristic; interpreting a PV cell IV characteristic and a PV cell breakdown profile; in response to the modular IV characteristic and the PV cell IV characteristics, determining a number of series PV cell sets and a number of parallel PV cells in each PV set; interpreting a modular active solar area; interpreting a nominal bypass diode number in response to the number of PV cell sets, the PV cell IV characteristics, and the PV cell breakdown profile; interpreting a geometric shape having a predetermined characteristic area value; and in response to the number of PV cell sets, the number of PV cells in each PV cell set, the modular active solar area, and the nominal bypass diode number, determining a spacing distribution of the PV cells and an adjusted bypass diode number.

In certain additional or alternative aspects, the disclosure includes the method having an operation including determining the parameter(s) as: a modular form factor requirement; a PV cell degradation profile; a bypass diode cost value; a modular degradation profile; a manufacturing cost function determined in response to the spacing distribution and the adjusted bypass diode number; a modular reliability profile; and/or a sensitivity value corresponding to any of the preceding parameters, and an operation including determining the spacing distribution of the PV cells and an adjusted bypass diode number is further in response to the parameter(s). In certain additional or alternative aspects, the disclosure includes the method including performing the determining the spacing distribution of the PV cells and an adjusted bypass diode number iteratively, manufacturing a building integrated photo-voltaic device in response to the spacing distribution of the PV cells and an adjusted bypass diode number, and/or manufacturing a building applied photo-voltaic device in response to the spacing distribution of the PV cells and an adjusted bypass diode number.

### BRIEF DESCRIPTION OF THE DRAWINGS

FIG. 1 is a schematic diagram of an article of manufacture having a number of PV cell sets.

FIG. 2 is a schematic diagram of a previously known PV device.

FIG. 3 is a schematic diagram of another embodiment of an article of manufacture having a number of PV cell sets.

FIG. 4 is an illustration of a number of notional geometric regions.

FIG. 5 is a schematic diagram of another embodiment of an article of manufacture having a number of PV cell sets.

FIG. 6 is a schematic diagram of another embodiment of an article of manufacture having a number of PV cell sets.

### DETAILED DESCRIPTION

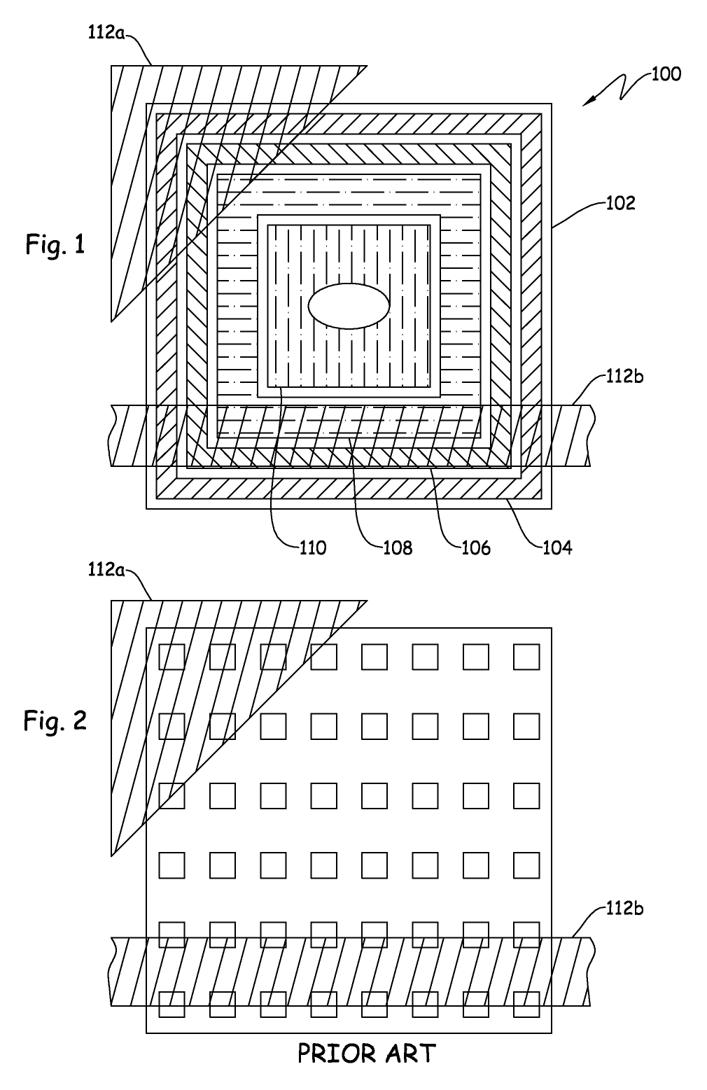

Referencing FIG. 1, a photovoltaic (PV) device 100 is schematically represented. The PV device 100 includes an active solar area 102 that defines a number of PV cell sets. Each PV cell set includes one or more PV cells. Where multiple PV cells form a PV cell set, the PV cells forming the PV cell set are coupled in a parallel electrical configuration. The PV device 100 includes four PV cell sets, 104, 106, 108, 110. The PV cell sets 104, 106, 108, 110 are arranged in a concentric framing arrangement. The concentric framing arrangement includes outer ones of the PV cell sets 104, 106, 108, 110 being positioned further from a geometric center of the active solar area 102. An outer concentric framing PV cell set may be positioned fully or partially outside of the inner concentric framing PV cell set (e.g. PV cell set 104 is positioned fully outside PV cell set 106). The concentric framing arrangement provides a favorable robustness to shading induced reverse biasing for a wide variety of geometric shapes.

The PV device 100 includes each one of the PV cell sets 104, 106, 108, 110 having a spacing distribution such that a geometric shape having a predetermined characteristic area value cannot be positioned to cover greater than a reverse biasing fraction of the PV cell set area of the corresponding PV cell set. The geometric shape may be any shape known in the art, for example a shape selected to approximate a known or standardized shading object. An example geometric shape 112a is depicted as a triangle overlaying a portion of the active solar area 102. The geometric shape 112a may be any portion of the entire shape, and may be oriented in any manner (position, angle, etc.) over the active solar area 102. Another example shape 112b is depicted in FIG. 1. The reverse biasing fraction of the PV cell set area of each PV cell set is an area that can be predetermined based upon the PV material of the PV cell sets, including the illuminated voltage of the PV material and the reverse biasing voltage of the PV material.

The determination of a spacing distribution that is sufficient to prevent reverse biasing is a mechanical step for one of skill in the art having the benefit of the disclosures herein and information generally available to one of skill in the art contemplating a particular PV device 100. The characteristics of the PV material define the fraction of the PV cell set area that causes reverse bias, and the shape and size of the geometric shape(s) provides the projected shading environment that the PV device 100 will be robust against. An example determination of a spacing distribution includes iteratively positioning the geometric shape 112a, 112b onto the active solar area 102, and determining whether any position can be achieved to block a reverse biasing fraction of any of the PV cell set areas. In certain embodiments, the state space of orientation and position possibilities of the geometric shape 112a,112b can be dramatically reduced by focusing on positioning values likely to cover a greater areal amount of a given PV cell set area. In certain embodiments, the PV cell sets have a spacing distribution such that a plurality of the PV cell sets cannot be subjected to a reverse bias from the geometric shape(s), but such that one or more of the PV cell sets can potentially experience a reverse bias from the geometric shape(s). In certain embodiments, the incremental warranty cost, manufacturing cost, and/or reliability of the PV device 100 can be improved even with one or more of the PV cell sets vulnerable to potential reverse biasing. In certain embodiments, all of the PV cell sets have a spacing distribution sufficient to prevent reverse biasing from the geometric shape(s).

Referencing FIG. 6, an alternate arrangement 700 of PV cell sets 702, 704, 706, 708, 710 includes the PV cell sets positioned in a concentric framing arrangement. An inner one of the PV cell sets 710 includes an excursive portion 712 that extends toward an outer edge of the solar active area. The excursive portion. 712 may extend to the outer edge, or a portion of the way toward the outer edge. The excursive portion 712 provides an option for a spacing distribution of the PV cell set 710 to avoid reverse biasing of the PV cell set 710 under the geometric shape(s). In certain embodiments, the inner one of the PV cell sets 710 includes two or more excursive portions 712. In certain embodiments, one or more of the outer concentric framing PV cell sets 702, 704, 706, 708 may be divided into two or more portions, for example where the excursive portions 712 pass therethrough, where the portions are electrically coupled in parallel.

Referencing FIG. 2, a previously known PV device includes a number of PV cells positioned in an active solar area. Individual PV cells in the device are not coupled in parallel to distant PV cells, and accordingly a geometric shape 112a, 112b is readily positioned in manner that reverse biases one or more PV cells. The previously known arrangement such as indicated in FIG. 2 is susceptible to shading induced degradation, and/or requires a large number of bypass diodes to avoid reverse biasing of individual PV cells.

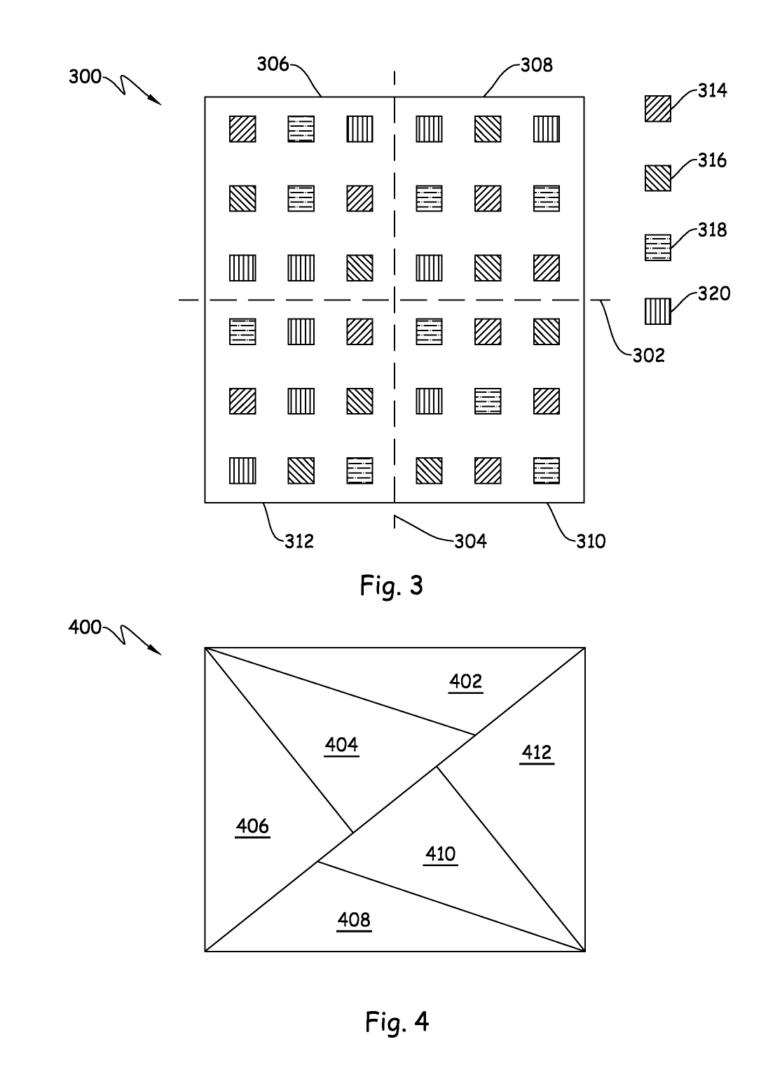

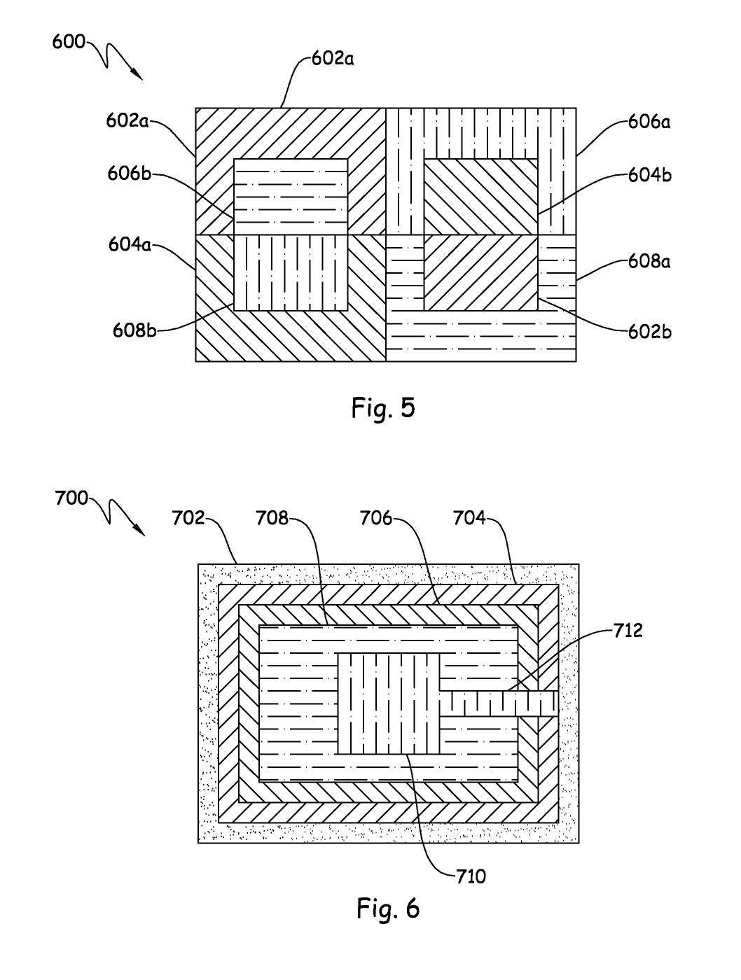

Referencing FIG. 3, a PV device 300 includes each of the PV cell sets 314, 316, 318, 320 having a number of PV cells electrically coupled in a parallel arrangement. The PV cell sets 314, 316, 318, 320 include a total area consisting of the total area of the PV cells within each PV cell set 314, 316, 318, 320. The PV cells of each PV cell set 314, 316, 318, 320 are spatially distributed around the active solar area of the PV device 300, such that a geometric shape (not shown) cannot be positioned such that one of the PV cell sets 314, 316, 318, 320 is placed into reverse bias.

In the example of FIG. 3, the PV device 300 is divided into a number of notional regions 306, 308, 310, 312. The divisions in the example are along a horizontal axis 302 and a vertical axis 304, although any division of notional regions is possible. The area of each notional region may be the same, approximately equivalent, or not equivalent. A notional region is an organizational concept, and not a physical feature appearing on the PV device 300. The use of notional regions 306, 308, 310, 312 provides for a convenient organizational system to ensure a minimal degree of distribution for each of the PV cell sets 314, 316, 318, 320 without intensive computation or calculation. Additionally or alternatively, individual cells of each PV cell set can be manually positioned about the PV device 300, and/or a mathematical description of the cell spatial distribution can be generated and utilized to provide an automated distribution that can be quantitatively described.

An example PV device 300 includes notional geometric regions, each having a height of at least two PV cells and a width of at least two PV cells. In certain embodiments, each of the PV cell sets 314, 316, 318, 320 includes at least one PV cell in each of two or more notional geometric regions. Additionally or alternatively, each of the PV cell sets 314, 316, 318, 320 includes at least one PV cell in each of the notional geometric regions. The PV device 300 includes four notional geometric regions, although a PV device may include any number of notional geometric regions, including between three and six notional geometric regions, inclusive. In certain embodiments, a PV cell may be considered to be within a notional geometric region if the PV cell is positioned entirely or partially within the notional geometric region.

Reference FIG. 4, a PV device 400 includes six notional geometric regions 402, 404, 406, 408, 410, 412. The shape of a notional geometric region may be arbitrary, selected to provide a desired distribution, selected for convenience of calculation or design of PV cell distributions, and/or selected according to a size and/or shape of the geometric shape(s).

An example PV device includes each PV cell set including PV cells having an even distribution throughout the notional geometric regions. Example even distributions include, without limitation, an equal number of PV cells in each notional geometric region, an equal area of PV cells in each notional geometric region, a number of PV cells that is as equal as possible in each notional geometric region (e.g. when the PV cells do not divide evenly into the notional geometric regions), an area of PV cells in each notional geometric region that is as even as possible (e.g. where the area of the PV cells has a discrete minimum quantum of area that does not allow completely equal distributions), any one of the preceding distributions which is prorated in each of the notional geometric regions by the area of each notional geometric region (e.g. a notional geometric region of area 2X includes twice as many PV cells, or twice the PV cell area, of a notional geometric region of area X), any one of the preceding distributions adjusted for rounding considerations, and/or any one of the preceding distributions which varies according to normal manufacturing tolerances. Any of the distributions into the notional geometric regions may be distributions into all of the notional geometric regions, or just distributions among the notional geometric regions wherein a given PV cell set appears.

In certain embodiments, the predetermined characteristic area value of the geometric shape includes a specified areal fraction of the active solar area. Example fractions include, without limitation, a predetermined characteristic area value that is between ⅓^{rd} and ½^{th}, between ½ and 1/10^{th}, between ½ and 1/15^{th}, and/or, between ½ and 1/20^{th} of the solar active area. The described size ranges are inclusive, and the ranges and corresponding implied number of PV cell sets within a PV device (e.g. three PV cell sets where each is ⅓^{rd} of the solar active area) are non-limiting examples. Each PV cell out may have the same area, and/or one or more of the PV cell sets may have a distinct area. The predetermined characteristic area value can be selected according to estimated shading factors, such as the size of a nominal or worst-case leaf from the foliage in the area, a size of a shading object determined through field observations of a number of PV devices in operation, a size of an object specified by a regulation, manufacturer specification, or original equipment manufacturer specification, or any other estimated shading factor known in the art. Additionally, or alternatively, the predetermined characteristic area value can be selected according to estimated PV device factors, such as the size of a shading object which is likely or virtually certain to trigger bypass diodes which prevent reverse biasing of PV cells. Example geometric shapes include a circle, an ellipse, a regular polygon, a square, a rectangle, a triangle, a quadrilateral, and/or a trapezoid. Geometric shapes may be combinations of these shapes, and/or may be entirely different shapes such as the shape of a common shading object (e.g. a leaf, loose roof tile, chimney corner, flag pole, etc.) or a shape specified by a regulation, manufacturer specification, or original equipment manufacturer specification, or any other estimated shading factor known in the art.

In certain embodiments, the reverse biasing fraction is a value bounded by a minimal fractional area and a maximal fraction area inclusively. An example minimal fractional area is an area that causes reverse biasing in the corresponding PV cell set, including a smallest area for a given shape that can, for a nominal design before a spatial distribution is determined or updated, induce reverse biasing in a PV cell set of interest at some position and orientation. An example maximal fractional area is an area that activates a bypass diode electrically coupled to the PV cell set of interest.

An example PV device includes the PV cell sets having a PV cell material, where a number of series PV cell sets associated with a bypass diode includes a value greater than n from Eq. 1:

$$n = \frac{{V}_{bypass} - {V}_{b}}{( 1 + β ( T - {T}_{0} ) ) {V}_{c}} \qquad Eq . 1$$

In the equation, n includes a nominal maximum number of series PV cell sets per bypass diode, V_{bypass} includes a bypass diode activation voltage, V_{b} includes a reverse breakdown voltage of the PV cell set material, V_{c} includes an operating voltage of the PV cell material when illuminated, T includes an operating temperature, T₀ includes a reference temperature, and β includes a voltage temperature coefficient. The values for the parameters in Eq. 1. are generally known to one of skill in the art contemplating a particular PV device configuration and PV cell material. Under previously known configurations, including greater than n series circuits on a bypass diode introduces a significant risk of reverse biasing and causing short-term power loss and long-term degradation. A PV device having PV cell sets with a spatial distribution as described herein greatly reduces the chance of a reverse biasing event, allowing for a relative reduction in the number of bypass diodes. In certain embodiments, the number of PV cell sets associated with each bypass diode is less than or equal to n. For example, the parameters in Eq. 1 can change with time and degradation, and some margin for aging or off-nominal manufacturing can be provided by increasing the number of bypass diodes, utilizing spatially distributed PV cell sets, or both.

Referencing FIG. 6, a PV device 600 includes a number of spatially distributed PV cell sets 602, 604, 606, 608. Each of the PV cell sets is divided into two PV cells (e.g. 602a, 602b) which are spatially distributed such that a predetermined geometric shape (not shown) cannot be positioned to shade a reverse biasing fraction of any one of the PV cell sets 602, 604, 606, 608. The example of FIG. 6 is an illustrative configuration and is not limiting.

The schematic flow description which follows provides an illustrative embodiment of performing procedures for designing an article of manufacture having a number of PV cell sets. The article of manufacture, in certain embodiments, is usable as a portion of a PV device, such as a building integrated PV device. Operations illustrated are understood to be exemplary only, and operations may be combined or divided, and added or removed, as well as re-ordered in whole or part, unless stated explicitly to the contrary herein. Certain operations illustrated may be implemented by a computer executing a computer program product on a computer readable medium, where the computer program product comprises instructions causing the computer to execute one or more of the operations, or to issue commands to other devices to execute one or more of the operations.

Certain operations described herein include operations to interpret one or more parameters. Interpreting, as utilized herein, includes receiving values by any method known in the art, including at least receiving values from a datalink or network communication, receiving an electronic signal (e.g. a voltage, frequency, current, or pulse-width modulated [PWM] signal) indicative of the value, receiving a software parameter indicative of the value, reading the value from a memory location on a non-transient computer readable storage medium, receiving the value as a run-time parameter by any means known in the art, by entry of a value by an operator or user, and/or by receiving a value by which the interpreted parameter can be calculated, and/or by referencing a default value that is interpreted to be the parameter value.

An example procedure includes an operation to interpret a modular current-voltage (IV) characteristic. The modular IV characteristic is an electrical output requirement for the entire PV device (e.g. PV device 100) and/or for a number of PV devices cooperating together. The modular IV characteristic may include a voltage, current, and/or power requirement, and may further include optimal or desired values, not-to-exceed (or fall below) limits, degradation requirements, uptime requirements, warranty requirements, or any other description of the module level performance requirement of the PV device.

An example procedure further includes an operation to interpret a PV cell IV characteristic and a PV cell breakdown profile. The PV cell IV characteristic includes the current and voltage performance of individual PV cells and/or PV cell sets, which are generally known according to manufacturer information, the PV materials utilized, the surrounding PV design (e.g. transparency, reflectiveness, internal losses, etc. due to the materials used in and design of barrier layers, encapsulation, electrical connections, etc.). The PV cell breakdown profile includes information utilized to determine the conditions of the PV cell set under which a reverse biasing event will occur, and includes information regarding the breakdown voltage of the PV material, temperature effects on the PV material, and/or consideration of any bypass diode properties.

The procedure includes, in response to the modular IV characteristic and the PV cell IV characteristics, determining a number of series PV cell sets and a number of parallel PV cells in each PV cell set. Determining a number of parallel PV cells in each cell set may include determining an area of each cell, and in certain embodiments each PV cell set may include only a single PV cell. The procedure further includes an operation to interpret a modular active solar area, and an operation to interpret a nominal bypass diode number in response to the number of PV cell sets, the PV cell IV characteristics, and the PV cell breakdown profile.

The procedure further includes an operation to interpret a geometric shape having a predetermined characteristic area value; and in response to the number of PV cell sets, the number of PV cells in each PV cell set, the modular active solar area, and the nominal bypass diode number, an operation to determine a spacing distribution of the PV cells and an adjusted bypass diode number.

In certain additional or alternative aspects, the procedure includes determining the spacing distribution and/or the adjusted bypass diode number with one or more additional operations. Example operations include: interpreting a modular form factor requirement (e.g. a maximum size, weight, thickness, etc.); interpreting a PV cell degradation profile (e.g. accounting for a loss of PV cell power deliverability, a change in the breakdown voltage, etc. in the later life of the PV material); interpreting a bypass diode cost value including without limitation the cost of the bypass diode(s) and/or related costs of manufacturing, warranty impact, and/or design complexity associated with the bypass diodes; interpreting a modular degradation profile including without limitation a modular electrical output requirement over time, degradation factors associated with the modular level (e.g. water intrusion, delamination, clouding of transparent materials) that can affect the life cycle cost/benefit of spatially distributed PV cell sets providing enhanced shading robustness; interpreting a manufacturing cost function determined in response to the spacing distribution and the adjusted bypass diode number (e.g. allowing optimization and/or incremental improvement of the spacing distribution and/or bypass diode design values); a modular reliability profile (e.g. requirements or targets for warranty costs and/or electrical output performance over time); and/or a sensitivity value corresponding to any of the preceding parameters. The operations to determine the spacing distribution of the PV cell sets and/or the adjusted bypass diode number, in certain embodiments, are further performed with consideration to one or more of the parameters described. Additionally or alternatively, the procedure includes an operation to determine the spacing distribution of the PV cells and/or an adjusted bypass diode number iteratively. The procedure provides operations to optimize, incrementally improve, and/or confirm a design of PV device, where the improvements or confirmations are directed to the robustness of the PV device to shading and/or to one or more aspects of the life cycle cost/benefit of the PV device. The life cycle of the PV device, as described herein, references a warranty period, marketed life cycle period, regulator period, and/or other selected period of time and/or operating parameter space (e.g. time of operation, energy delivered, etc.).

In certain embodiments, the procedure includes an operation to manufacture a building integrated photo-voltaic device, for example a solar roofing tile, in response to the spacing distribution of the PV cells and the adjusted bypass diode number. Additionally or alternatively, an example procedure includes an operation to manufacture a building applied photo-voltaic device, for example a roof mounted module, in response to the spacing distribution of the PV cells and the adjusted bypass diode number.

Any numerical values recited in the above application include all values from the lower value to the upper value in increments of one unit provided that there is a separation of at least 2 units between any lower value and any higher value. As an example, if it is stated that the amount of a component or a value of a process variable such as, for example, temperature, pressure, time and the like is, for example, from 1 to 90, further including from 20 to 80, also including from 30 to 70, it is intended that values such as 15 to 85, 22 to 68, 43 to 51, 30 to 32 etc. are expressly enumerated in this disclosure. One unit is considered to be the most precise unit disclosed, such as 0.0001, 0.001, 0.01 or 0.1 as appropriate. These are only examples of what is specifically intended and all possible combinations of numerical values between the lowest value and the highest value enumerated are to be considered to be expressly stated in this disclosure in a similar manner.

Unless otherwise stated, all ranges include both endpoints and all numbers between the endpoints. The disclosures of all articles and references, including patent applications and publications, are incorporated by reference for all purposes. The use of the terms “comprising” or “including” describing combinations of elements, ingredients, components or steps herein also contemplates embodiments that consist essentially of the elements, ingredients, components or steps. The use of the articles “a” or “an,” and/or the disclosure of a single item or feature, contemplates the presence of more than one of the item or feature unless explicitly stated to the contrary.

Example embodiments of the present invention have been disclosed. A person of ordinary skill in the art will realize however, that certain modifications to the disclosed embodiments come within the teachings of this disclosure. Therefore, the following claims should be studied to determine the true scope and content of the invention.

What is claimed is:

1. An article of manufacture, comprising:
an active solar area defining a plurality of photovoltaic (PV) cell sets, each PV cell set comprising a PV cell set area; and
wherein each of the PV cell sets comprise a spacing distribution such that a geometric shape having a predetermined characteristic area value cannot be positioned to cover greater than a reverse biasing fraction of the PV cell set area of the corresponding PV cell set.

2. The article of claim 1, wherein each of the PV cell sets further comprises a number of PV cells electrically coupled in a parallel arrangement, and wherein the PV cell set area corresponding to each of the PV cell sets consists of the total area of the number of PV cells of the PV cell set.

3. The article of claim 2, the active solar area further comprising a plurality of notional geometric regions, wherein each of the notional geometric regions comprises a height of at least two PV cell heights, a width of at least two PV cell widths, and wherein each of the PV cell sets includes PV cells from the number of cells distributed to a plurality of the notional geometric regions.

4. The article of claim 3, further comprising between three and six notional geometric regions, inclusive.

5. The article of claim 3, wherein the notional geometric regions comprise equal areas.

6. The article of claim 3, wherein each of the PV cell sets includes at least one PV cell positioned within each of the notional geometric regions.

7. The article of claim 6, wherein the PV cells from each of the PV cell sets comprise an even distribution throughout the notional geometric regions.

8. The article of claim 7, wherein the even distribution comprises at least one distribution selected from the distributions consisting of:
an equal number of PV cells from each PV cell set to each notional geometric region;
an equal area of PV cells from each PV cell set to each notional geometric region;
a prorated number of PV cells from each PV cell set to each notional geometric region, the prorated number determined in response to an area of each notional geometric region;
a prorated area of PV cells from each PV cell set to each notional geometric region;
the prorated area determined in response to an area of each notional geometric region; and
any one of the preceding distributions, further comprising a rounding adjustment.

9. The article of claim 1, wherein the predetermined characteristic area value comprises an areal fraction of the active solar area between ⅓^{rd} and 1/12^{th} inclusive.

10. The article of claim 1, wherein the predetermined characteristic area value comprises an areal fraction of the active solar area selected from the areal fractions consisting of: between ½ and 1/10^{th} inclusive; between ½ and 1/15^{th} inclusive; and between ½ and 1/20^{th} inclusive.

11. The article of claim 1, wherein the geometric shape comprises at least one shape selected from the shapes consisting of: a circle, an ellipse, a regular polygon, a square, a rectangle, a triangle, a quadrilateral, and a trapezoid.

12. The article of claim 1, wherein the reverse biasing fraction comprises a value between, inclusively:
a minimal fractional area of the PV cell set area that causes reverse biasing in the PV cell set; and
a maximal fractional area that activates a bypass diode electrically coupled to the PV cell set.

13. The article of claim 1, wherein the PV cell sets comprise a PV cell material, and wherein a number of series PV cell sets associated with a bypass diode comprises a value greater than n from the equation:
$$n = \frac{{V}_{bypass} - {V}_{b}}{( 1 + β ( T - {T}_{0} ) ) {V}_{c}} ;$$
wherein n comprises a nominal maximum number of series PV cell sets per bypass diode, V_{bypass} comprises a bypass diode activation voltage, V_{b} comprises a reverse breakdown voltage of the PV cell set material, V_{c} comprises an operating voltage of the PV cell material when illuminated, T comprises an operating temperature, T₀ comprises a reference temperature, and β comprises a voltage temperature coefficient.

14. The article of claim 1, wherein the PV cell sets are arranged in a concentric framing arrangement.

15. The article of claim 14, wherein an inner one of the PV cell sets further comprises an excursive portion extending toward an outer edge of the active solar area.

16. A method, comprising:
interpreting a modular current-voltage (IV) characteristic;
interpreting a PV cell IV characteristic and a PV cell breakdown profile;
in response to the modular IV characteristic and the PV cell IV characteristics, determining a number of series PV cell sets and a number of parallel PV cells in each PV cell set;
interpreting a modular active solar area;
interpreting a nominal bypass diode number in response to the number of PV cell sets, the PV cell IV characteristics, and the PV cell breakdown profile;
interpreting a geometric shape having a predetermined characteristic area value; and
in response to the number of PV cell sets, the number of PV cells in each PV cell set, the modular active solar area, and the nominal bypass diode number, determining a spacing distribution of the PV cells and an adjusted bypass diode number.

17. The method of claim 16, further comprising:
determining at least one parameter selected from the list of parameters consisting of: a modular form factor requirement; a PV cell degradation profile; a bypass diode cost value; a modular degradation profile; a manufacturing cost function determined in response to the spacing distribution and the adjusted bypass diode number; a modular reliability profile; and a sensitivity value corresponding to any of the preceding parameters; and
wherein the determining the spacing distribution of the PV cells and an adjusted bypass diode number is further in response to the at least one parameter.

18. The method according to claim 16, further comprising performing the determining the spacing distribution of the PV cells and an adjusted bypass diode number iteratively.

19. The method according to claim 16, further comprising manufacturing one of a building integrated photo-voltaic device and a building applied photovoltaic device in response to the spacing distribution of the PV cells and an adjusted bypass diode number.
